(19) United States
(12) Patent Application Publication
(10) Pub. No.: US 2025/0006433 A1
(43) Pub. Date: Jan. 2, 2025

(54) THIN HAFNIUM-ZIRCONIUM OXIDE FILMS HAVING LARGE GRAIN SIZE FOR FERROELECTRIC CAPACITORS

(71) Applicant: Intel Corporation, Santa Clara, CA (US)

(72) Inventors: Sarah Atanasov, Beaverton, OR (US); Elijah Karpov, Portland, OR (US); Nazila Haratipour, Portland, OR (US); Sou-Chi Chang, Portland, OR (US); Tristan Tronic, Aloha, OR (US)

(73) Assignee: Intel Corporation, Santa Clara, CA (US)

(21) Appl. No.: 18/216,479

(22) Filed: Jun. 29, 2023

(51) Int. Cl. H01G 7/06; H10B 53/00

(52) U.S. Cl. CPC H01G 7/06; H01L 28/60; H10B 53/00

(57) ABSTRACT

Apparatuses, memory systems, capacitor structures, and techniques related to ferroelectric capacitors having a hafnium-zirconium oxide film between the electrodes of the capacitor are discussed. The hafnium-zirconium oxide film is thin and has large crystallite grains. The thin large grain hafnium-zirconium oxide film having large grains is formed by depositing a thick hafnium-zirconium oxide film and annealing the thick hafnium-zirconium oxide film to establish the large grain size, and etching back the hafnium-zirconium oxide film to the desired thickness for deployment in the ferroelectric capacitor.

### BACKGROUND

Ferroelectric memory devices such as random-access memory (RAM) use a ferroelectric material in place of the dielectric material deployed in the capacitor of a typical dynamic random-access memory (DRAM). Such ferroelectric memory devices have promising characteristics such as lower power usage, fast write performance, and others. However, difficulties arise in deploying ferroelectric material systems. For example, hafnium-based ferroelectric memory used in high-speed high-density memory applications has difficulty with respect to meeting polarization requirements, variability requirements, high endurance requirements in terms of read/write endurance cycles, and others, particularly at reduced dimensions. For example, thin ferroelectric materials are desirable to operate the capacitor devices at lower voltages and to scale down devices for greater density and other advantages. However, thin hafnium-based ferroelectric films are particularly susceptible to the problems discussed above.

It is with respect to these and other considerations that the present improvements have been needed. Such improvements may become critical as the desire to deploy advanced memory solutions becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a schematic of an example ferroelectric capacitor;

FIG. 1B illustrates a diagram of an example memory cell circuit;

FIG. 1C illustrates a plot showing polarization versus voltage for a capacitor deploying a ferroelectric material;

FIG. 2 illustrates a cross-sectional side view and a cross-sectional top-down view of an exemplary deep trench capacitor having a thin ferroelectric layer including hafnium, zirconium, and oxygen with large crystalline grains or crystallites;

FIG. 3 illustrates a cross-sectional side view of the ferroelectric film of FIG. 2 taken along a lateral portion of the ferroelectric film illustrating large crystalline grains or crystallites;

FIG. 4 illustrates a cross-sectional side view of the ferroelectric film of FIG. 2 taken along a vertical portion of the ferroelectric film illustrating large crystalline grains or crystallites;

FIG. 5 is a chart illustrating exemplary ferroelectric layer characteristics inclusive of thickness and grain size as the ferroelectric layer is grown and subsequently etched back;

FIG. 6 is a flow diagram illustrating methods for forming a capacitor having a thin ferroelectric layer including hafnium, zirconium, and oxygen with large crystalline grains or crystallites;

FIGS. 7A, 7B, 7C, 7D, 7E, 7F, 7G, 7H, 7I, 7J, and 7K are cross-sectional views of capacitor structures evolving as the methods of FIG. 6 are practiced;

FIG. 8 illustrates a cross-sectional side view of an exemplary deep trench capacitor having a thin ferroelectric layer including hafnium, zirconium, and oxygen with large crystalline grains or crystallites;

FIG. 9 illustrates a cross-section of an embedded dynamic random-access memory including capacitor having a thin ferroelectric layer including hafnium, zirconium, and oxygen with large crystalline grains or crystallites;

FIG. 10 illustrates a cross-sectional side view of a multiple capacitor stacked memory device 1000 including capacitors having a thin ferroelectric layer including hafnium, zirconium, and oxygen with large crystalline grains or crystallites;

FIG. 11 illustrates exemplary systems employing an integrated circuit die including a memory having a thin ferroelectric layer including hafnium, zirconium, and oxygen with large crystalline grains or crystallites; and

FIG. 12 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 95% of the particular material or component and “pure” indicates not less than 99% of the particular material or component. Unless otherwise indicated, such material percentages are based on atomic percentage. As used herein, the terms “monolithic”, “monolithically integrated”, and similar terms indicate the components of the monolithic overall structure form an indivisible whole not reasonably capable of being separated.

Apparatuses, systems, capacitor structures, memory devices, and techniques are described herein related to ferroelectric capacitors deploying a thin capacitor ferroelectric film having large crystallite grains.

As discussed, hafnium-based ferroelectric materials may be used in high-speed high-density memory applications. Currently, such material systems have difficulties with respect to polarization, variability, endurance, and others, particularly at reduced dimensions. For example, it is desirable to deploy thin ferroelectric materials such that the capacitor device can be operated at low voltages. However, such thin ferroelectric material layers (e.g., about 2 to 5 nm) have relatively low polarity, high variability, and low endurance.

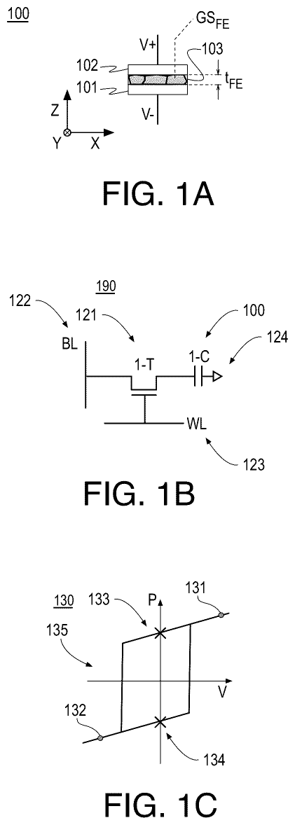

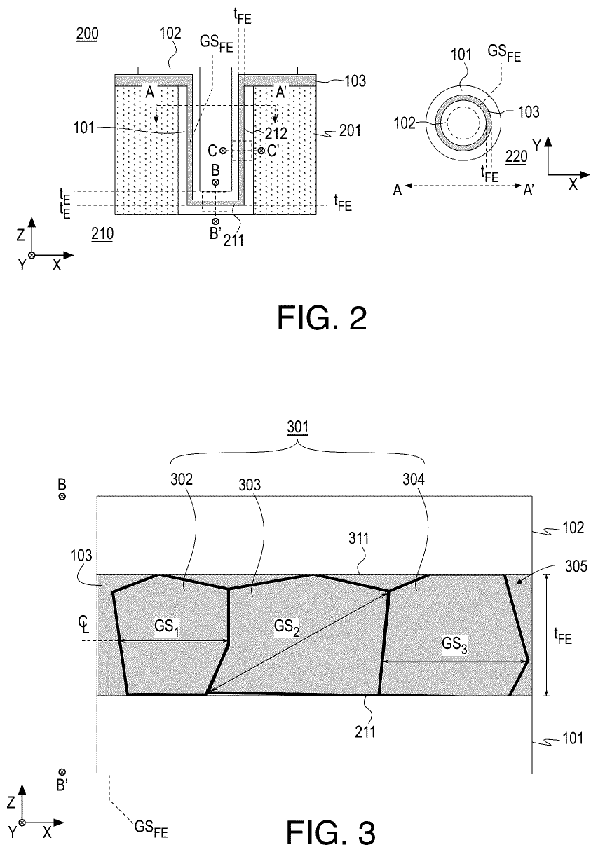

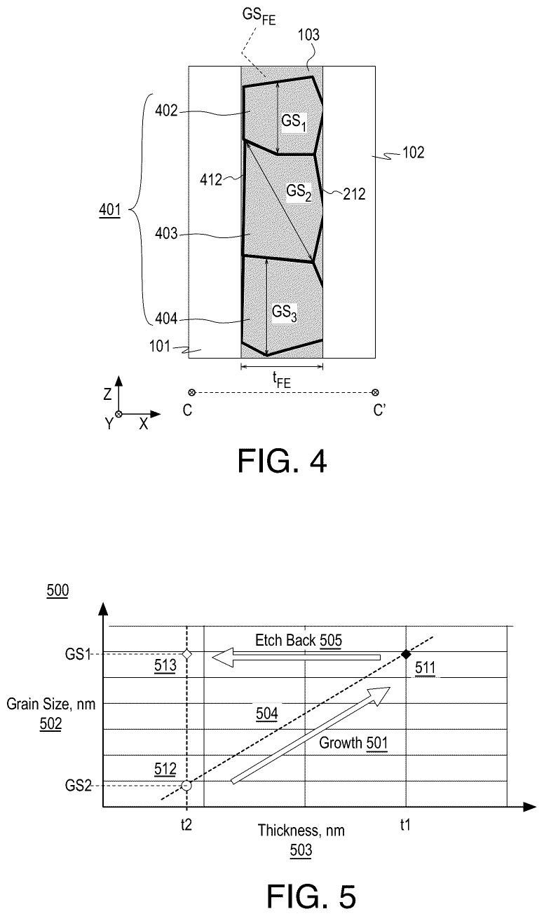

Embodiments discussed herein provide for the fabrication of large grain size hafnium-zirconium oxide (HZO) films suitable for deployment in capacitors at reduced dimensions (e.g., very thin HZO films). For example, capacitors or capacitor structures include first and second electrodes separated by a ferroelectric material layer or film that includes hafnium, zirconium, and oxygen. For example, the ferroelectric material layer or film may be a polycrystalline hafnium-zirconium oxide material having any suitable proportions of hafnium and zirconium such as stoichiometric hafnium and zirconium (e.g., 1:1) or others including higher levels of zirconium. As used herein, the terms ferroelectric material layer, ferroelectric film, or similar terms indicate a material having a spontaneous electric polarization that can be reversed by the application of an external electric field, as discussed herein with respect to FIGS. 1A-IC. The ferroelectric material layer or film has a thickness between the first and second electrodes such that the ferroelectric material layer or film is very thin. For example, the thickness between the first and second electrodes may be in the range of about 2 to 5 nm. In the context of the thickness between the first and second electrodes, the thickness is measured along an axis substantially orthogonal to the first and second electrodes.

Furthermore, the ferroelectric material layer or film has a number of grains or crystallites within the material layer or film. As used herein, the term grain or crystallite indicates a small crystal within a material. For example, the grains or crystals may be formed during deposition of the material and/or a subsequent anneal operation. In some contexts, the deposition is an atomic layer deposition (ALD) and the subsequent anneal is a relatively high temperature (e.g., 500° C. or above) and relatively short (e.g., 10 to 30 second) anneal. However, any suitable deposition and/or anneal processes may be used. The discussed grains of the ferroelectric material layer define a grain size of the grains and of the material layer itself. This characteristic grain size of the ferroelectric material layer or film may be determined using any suitable technique or techniques such as cross sectioning the material, outlining grain boundaries, and measuring across the grains. The grain size may be a maximum distance across the grain (in any orientation), a maximum distance across the grain orthogonal to the discussed thickness of the film (e.g., along a lateral orientation of the film), a distance across the grain orthogonal to the discussed thickness at a centerline of the grain, or other dimension. The grain size of the film may then be taken as a maximum grain sizes in the sample, an average of grain size in the sample, or the like.

As discussed, the thin ferroelectric material layer or film offers of the advantage of low voltage capacitor operation, which in turn leads to more energy efficient memory systems. The large grain size of the ferroelectric material layer or film offers the advantage of improved polarization and variability of the ferroelectric material layer or film. For example, the grain size may be substantially larger than the film thickness such as five times larger, eight times larger, ten times larger, or more. For example, a ferroelectric material layer or film may have a 30 nm grain size in a 3 nm thick film. This ratio of grain size to thickness is achieved by first growing a thick HZO ferroelectric material layer or film on or over a bottom electrode (e.g., a TiN electrode). As discussed further herein, by growing a thick HZO film (and with subsequent anneal processing), the HZO ferroelectric material layer or film has large grain sizes. In some embodiments, a sacrificial top metal layer such as a TiN layer is formed on the thick HZO ferroelectric material layer or film prior to anneal and removed after the anneal sets the large grain size of the HZO ferroelectric material layer or film. The HZO ferroelectric material layer or film with large grain size is then etched back using, for example, atomic layer etch (ALE). This ALE may be used to reduce the thickness with great control and low variability to a desired thickness of the HZO ferroelectric material layer or film. Furthermore, the processing does not affect the grain size, and, for example, the lateral grain size of the film is maintained after etch back. A top electrode (e.g., a TiN electrode) may then be formed on the HZO ferroelectric material layer or film.

Thereby, a thin (e.g., 2-5 nm) HZO ferroelectric material layer or film having large grain sizes (e.g., 15-30 nm or more) is provided for the capacitor. The HZO ferroelectric material layer or film offers the advantages of low voltage operation, high polarization, low variability, high endurance, and others. This optimizes the film to maximize polarization while maintaining low operation voltage.

FIG. 1A illustrates a schematic of an example ferroelectric capacitor 100, arranged in accordance with at least some implementations of the present disclosure. As shown in FIG. 1A, ferroelectric capacitor 100 includes a ferroelectric film 103 between electrodes 101, 102. As discussed in detail herein, ferroelectric film 103 is a thin ferroelectric layer including hafnium, zirconium, and oxygen (e.g., an HZO layer) having large crystalline grains or crystallites. The terms thin film and large grain in the context of ferroelectric film 103 are discussed further herein below. For example, ferroelectric film 103 may have a thickness of t_{FE} and a grain size G_{FE} as discussed below. In some embodiments, ferroelectric capacitor 100 may also include interfacial layers between ferroelectric film 103 and each of electrodes 101, 102.

FIG. 1B illustrates a diagram of an example memory cell circuit 190, arranged in accordance with at least some implementations of the present disclosure. As shown in FIG. 1B, ferroelectric capacitor 100 may be deployed in memory cell circuit 190, which provides a one capacitor-one transistor (1C-1T) architecture. Such 1C-1T architectures may be deployed in a variety of contexts including capacitor over bit line (COB) architectures (e.g., deep trench architectures), 3D array memory device architectures (e.g., vertically stacked capacitor architectures), or others. As shown, memory cell circuit 190 includes ferroelectric capacitor 100 and a transistor 121. Transistor 121 may have any suitable architecture. For example, transistor 121 may be a planar field effect transistor (FET), a FinFET, a gate all around (GAA) transistor (GAA-FET), or other. The gate of transistor 121 is controlled via a word line 123 and the source/drain of transistor 121 are coupled to ferroelectric capacitor 100 and a bit line 122. Ferroelectric capacitor 100 is further coupled to a ground 124.

As discussed, in some contexts, memory devices may deploy a thin ferroelectric layer including hafnium, zirconium, and oxygen (e.g., an HZO layer) having large crystalline grains or crystallites. Notably, any suitable capacitor or capacitor structure such as ferroelectric capacitor 100 and those discussed elsewhere herein may be incorporated in memory cell circuit 190 or any other higher-level apparatus, system, structure, or device discussed elsewhere herein. Notably, memory devices deploying a thin ferroelectric layer including hafnium, zirconium, and oxygen (e.g., an HZO layer) having large crystalline grains or crystallites offers the advantage of low voltage operation of, for example, memory cell circuit 190.

FIG. 1C illustrates a plot 130 showing polarization versus voltage for a capacitor deploying a ferroelectric material, arranged in accordance with at least some implementations of the present disclosure. Unlike a typical dielectric based capacitor, a ferroelectric capacitor uses polarization charge to store the memory states, where a positive polarization charge state 133 indicates, for example, a stored bit of “1” and a negative polarization charge state 134, indicate, for example, a stored bit of “0”. Plot 130 illustrates the hysteresis property of a ferroelectric material-based capacitor.

A ferroelectric material exhibits ferroelectricity, which is a property by which a spontaneous electric polarization can be revered by an electric field (e.g., applied voltage). For example, when a dielectric material is polarized, the induced polarization is proportional to the applied external electric field. Ferroelectric materials, on the other hand, demonstrate a spontaneous non-zero polarization even when the applied electric field is zero. As such, the spontaneous polarization may be reversed by an applied electric field in the opposite direction. This results in a hysteresis loop 135 because the polarization of a ferroelectric material is dependent not only on the present electric field but also on its history. Hysteresis loop 135 of plot 130 shows two stable operating positions or states for a ferroelectric capacitor, as discussed above: positive polarization charge state 133 and negative polarization charge state 134. These stable charge states 133, 134 indicate that the direction of polarization can be switched from one to another by application, for example, of positive switching voltage 131 and negative switching voltage 132. For example, polarization may be defined as the difference between stable charge states 133, 134 (e.g., an on state and an off state). Notably, memory devices deploying a thin ferroelectric layer including hafnium, zirconium, and oxygen (e.g., an HZO layer) having large crystalline grains or crystallites offers the advantage of increased polarization (e.g., increased difference between charge states 133, 134) during operation of, for example, memory cell circuit 190.

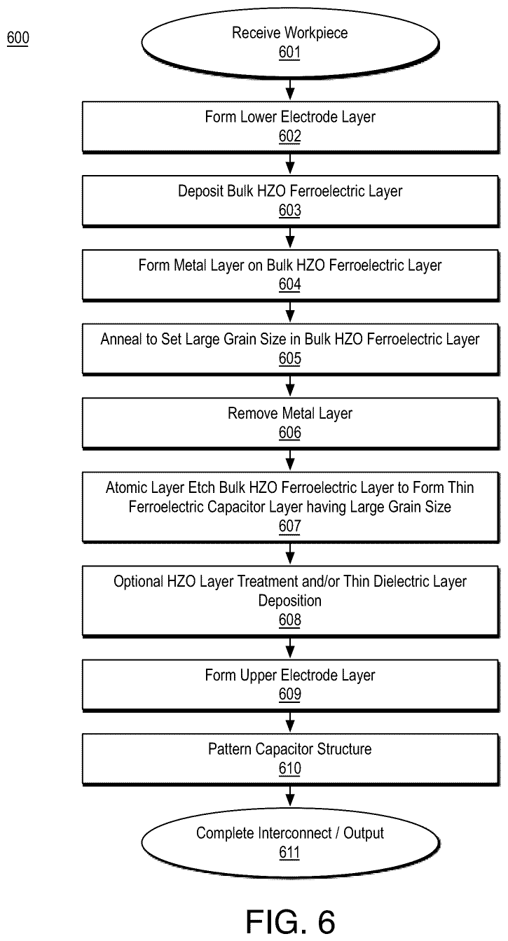

FIG. 2 illustrates a cross-sectional side view 210 and a cross-sectional top-down view 220 of an exemplary deep trench capacitor 200 having a thin ferroelectric layer including hafnium, zirconium, and oxygen with large crystalline grains or crystallites, arranged in accordance with some embodiments of the disclosure. For example, deep trench capacitor 200 may be deployed over a bit line (i.e., capacitor over bit line, COB), as discussed herein below. Deep trench architectures increase capacitor surface area, and deep trench capacitor 200 may have a U-shape (as shown) or a V-shape in cross-sectional. As shown, deep trench capacitor 200 includes electrode 101, electrode 102, and ferroelectric film 103 therebetween within a dielectric material 201. As shown with respect to the cross-sectional top-down view, in some embodiments, one or more of electrode 101, electrode 102, and ferroelectric film 103 have an annular shape having an inner and outer shape that are substantially circular. However, other shapes such as rectangular, square, ovular, and others may be used. Deep trench capacitor 200 is coupled to other devices using metal interconnects as discussed herein below. Although illustrated with respect to deep trench capacitor 200, the pertinent characteristics of electrode 101, electrode 102, and ferroelectric film 103 may be deployed in any capacitor or capacitor structure context herein such as a planar capacitor architecture, a stacked capacitor architecture, or the like.

As shown, deep trench capacitor 200 includes a first or bottom electrode 101. Electrode 101 may include any suitable conductive material such as a metal. In some embodiments, electrode 101 is or includes titanium nitride (TiN, e.g., titanium and nitrogen). In some embodiments, electrode 101 is or includes tungsten (W), tantalum nitride (TaN, e.g., tantalum and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt). Similarly, second or top electrode 102 may include any suitable conductive material such as a metal. In some embodiments, electrode 102 is or includes titanium nitride (TiN, e.g., titanium and nitrogen). In some embodiments, electrode 102 is or includes tungsten (W), tantalum nitride (TaN, e.g., tantalum and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt). The material(s) deployed in bottom electrode 101 and top electrode 102 may be the same or they may be different

Electrode 101 and electrode 102 may have any suitable thicknesses the such as a thickness in the range of 5 nm to 20 nm. In some embodiments, electrode 101 and electrode 102 have thicknesses the in the range of 5 nm to 10 nm. In some embodiments, electrode 101 and electrode 102 have thicknesses the in the range of not less than 5 nm. It is noted that with respect to electrode 101 and electrode 102 and other conformal layers, the thickness of the layer or film may be measured in the vertical direction (e.g., z-dimension) when the layer is formed on a lateral layer (e.g., having a surface in the x-y plane) or orthogonal to the surface on which the layer is formed. For example, the thickness of the layer may be in the horizontal direction (e.g., x- or y-dimension) when taken at a portion of the film extending in the vertical direction or at a normal dimension when taken at a portion of the film extending in another plane. The thicknesses t_{E} of electrode 101 and electrode 102 may be the same or they may be different.

As shown, a ferroelectric film 103 (or ferroelectric material layer, ferroelectric material, or the like) is between electrode 101 and electrode 102. In some embodiments, ferroelectric film 103 is on one or both of electrode 101 and electrode 102. In some embodiments, an intervening layer may be between ferroelectric film 103 and one or both of electrode 101 and electrode 102. Ferroelectric film 103 includes hafnium, zirconium, and oxygen. For example, ferroelectric film 103 may be or include HZO. In some embodiments, ferroelectric film 103 is substantially pure HZO. In some embodiments, ferroelectric film 103 is pure HZO. In some embodiments, ferroelectric film 103 is doped HZO. For example, ferroelectric film 103 may be HZO doped with dopants including one or more of lanthanum, yttrium, silicon, or others. In some embodiments, ferroelectric film 103 is stoichiometric HZO having a hafnium to zirconium ratio of about 1:1. However, the HZO of ferroelectric film 103 may have any suitable ratio such as greater proportions of zirconium.

Ferroelectric film 103 may have any suitable thickness t_{FE} orthogonal a lateral surface 211 of electrode 101 and/or orthogonal a sidewall surface 212 (e.g., a vertical surface) of electrode 101. As used herein the term lateral indicates a surface in the x-y plane and vertical surface indicates a plane extending in the z-dimension with the z-dimension being aligned with a buildup direction of the device. Similarly, ferroelectric film 103 may have thickness t_{FE} orthogonal to electrode 101 in any direction normal to a surface of electrode 101. In some embodiments, ferroelectric film 103 has a thickness t_{FE} in the range of 2 to 5 nm. In some embodiments, thickness t_{FE} is in the range of 3 to 10 nm. In some embodiments, thickness t_{FE} is not more than 5 nm. In some embodiments, thickness t_{FE} is not more than 3 nm. Other thicknesses may be used.

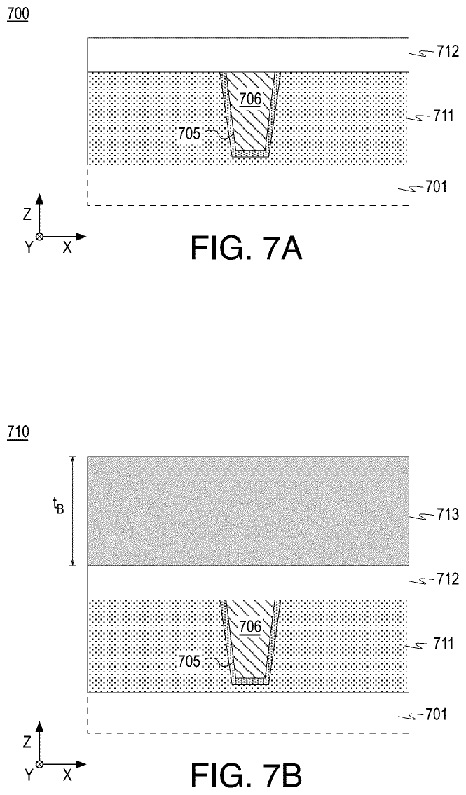

FIG. 3 illustrates a cross-sectional side view of ferroelectric film 103 taken along a lateral portion of ferroelectric film 103 illustrating large crystalline grains or crystallites 301, arranged in accordance with some embodiments of the disclosure. The cross-sectional side view of ferroelectric film 103 in FIG. 3 is taken at cross-section B-B′ in FIG. 2. As shown, thickness t_{FE} of ferroelectric film 103 is orthogonal to lateral surface 211 of electrode 101 and lateral surface 311 of electrode 102 such that ferroelectric film 103 extends between electrodes 101, 102 and thickness t_{FE} also extends between electrodes 101, 102 (e.g., orthogonal to lateral surfaces 211, 311).

Ferroelectric film 103 includes hafnium, zirconium, and oxygen. For example, ferroelectric film 103 may be substantially pure or pure HZO. Ferroelectric film 103 includes large crystalline grains 301, which are generated as discussed herein below with respect to methods 600. As shown, a grain size for each of grains 302, 303, 304 (or for samples of grains) may be determined using any suitable technique or techniques. In some embodiments, grains 302, 303, 304 may be identified by cross-sectioning ferroelectric film 103, imaging the cross-section (e.g., using transmission electron microscopy, TEM), and labeling grain boundaries 305, either manually or using automated software. The grain size for each of grains 302, 303, 304 may then be determined using any suitable technique or techniques such as measuring across the grain.

In some embodiments, as shown with respect to grain 302, the grain size may be measured as a distance GS₁ across a centerline (CL) of grain 302 such that the centerline is orthogonal to thickness t_{FE}. For example, using measurements aligned with the x-y plane (and orthogonal to thickness t_{FE}) may be used as ferroelectric film 103 is etched back to thickness t_{FE}, as discussed further herein below. For example, the grain size of each of grains 302, 303, 304 may be determined as a distance between lateral grain boundaries 305 of each grains 302, 303, 304 taken at the centerline of grains 302, 303, 304 such that the centerline is orthogonal to thickness t_{FE}. The centerline may be taken as the centerline of each of grains 302, 303, 304 or as a centerline of ferroelectric film 103.

In some embodiments, as shown with respect to grain 303, the grain size may be measured as a maximum distance GS₂ across grain 303 such that the maximum distance GS₂ is determined as the greatest distance cross grain 303 in the x-z plane (e.g., along the cross-section). For example, using a maximum distance in the x-z plane may be used as indicative of the grain size of each of grains 302, 303, 304. For example, the grain size of each of grains 302, 303, 304 may be determined as a maximum distance between grain boundaries 305 of each grains 302, 303, 304 taken in any orientation in the x-z plane.

In some embodiments, as shown with respect to grain 304, the grain size may be measured as a maximum distance GS₃ across grain 304 attained along a line orthogonal to thickness t_{FE}. For example, horizontal scan lines may be run across vertical positions (e.g., positions in the z-dimensions) of grain 304, and the maximum measured distance across grain 304 may be used as grain size GS₃. As discussed, using measurements aligned with the x-y plane (and orthogonal to thickness t_{FE}) may be suitably used as ferroelectric film 103 is etched back to thickness t_{FE}, as discussed further herein below. For example, the grain size of each of grains 302, 303, 304 may be determined as a distance between lateral grain boundaries 305 of each grains 302, 303, 304 taken along any line orthogonal to thickness t_{FE}.

Once the grain sizes of grains 302, 303, 304 are determined, a grain size GS_{FE} of ferroelectric film 103 may be determined using any suitable technique or techniques. In some embodiments, grain size GS_{FE} of ferroelectric film 103 is the mean of the grain sizes. In some embodiments, grain size GS_{FE} of ferroelectric film 103 is the median of the grain sizes. In some embodiments, grain size GS_{FE} of ferroelectric film 103 is the maximum of the grain sizes. The sample of grains (e.g., number of grains) may be determined using any suitable technique or techniques such as selecting and measuring all grains in a sample, measuring only selected grains, or measuring only a single grain. Furthermore, it is understood that only grains of a particular size and quality qualify for measurement and that interstitial regions and/or defects are not grains or crystallites, by definition. Thereby a grain size GS_{FE} of ferroelectric film 103 and/or grain size GS_{FE} of the grains or crystallites of ferroelectric film is determined.

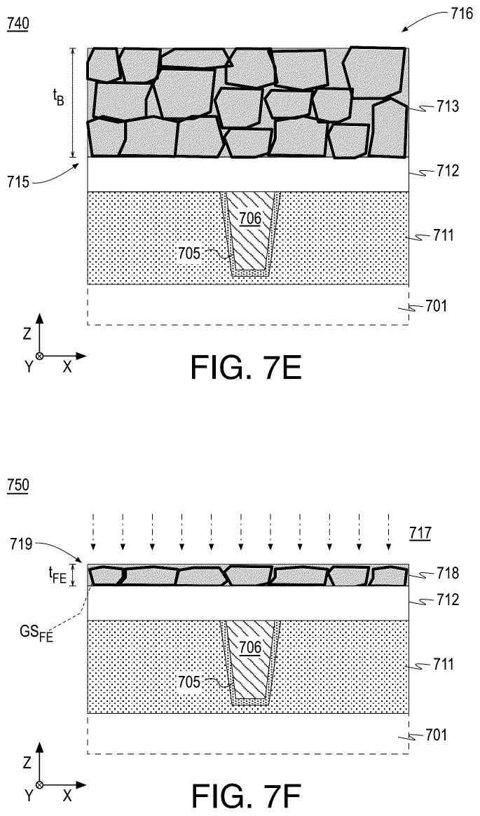

As discussed, the grain size GS_{FE} is large in reference to thickness t_{FE} of ferroelectric film 103. In some embodiments, the grain size GS_{FE} is not less than 15 nm. In some embodiments, the grain size GS_{FE} is not less than 20 nm. In some embodiments, the grain size GS_{FE} is not less than 25 nm. In some embodiments, the grain size GS_{FE} is in the range of 25 to 35 nm. Furthermore, a ratio of the grain size GS_{FE} to the thickness t_{FE} may be not less than five. That is, the grain size GS_{FE} of ferroelectric film 103 may be not less than five times the thickness t_{FE} of ferroelectric film 103. In some embodiments, the ratio of the grain size GS_{FE} to the thickness t_{FE} may be not less than eight. ratio of the grain size GS_{FE} to the thickness t_{FE} may be not less than ten. Other ratios may be deployed. Such exemplary grain sizes to thicknesses and ratios are discussed further with respect to FIG. 5 below.

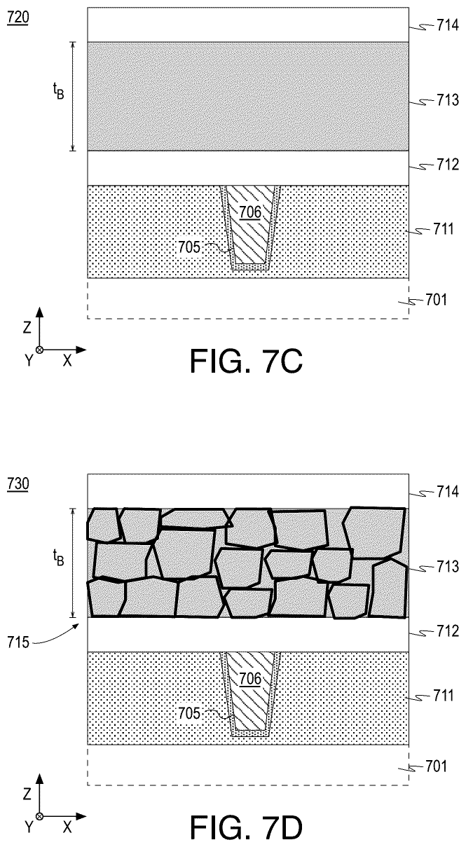

FIG. 4 illustrates a cross-sectional side view of ferroelectric film 103 taken along a vertical portion of ferroelectric film 103 illustrating large crystalline grains or crystallites 401, arranged in accordance with some embodiments of the disclosure. The cross-sectional side view of ferroelectric film 103 in FIG. 4 is taken at cross-section C-C′ in FIG. 2. As shown, thickness t_{FE} of ferroelectric film 103 is orthogonal to sidewall surface 212 of electrode 101 and a sidewall surface 412 (or vertical surface) of electrode 102 (or any surface of electrodes 101, 102) such that ferroelectric film 103 extends between electrodes 101, 102 and thickness t_{FE} also extends between electrodes 101, 102 (e.g., orthogonal to sidewall surface 212, 412).

As discussed, ferroelectric film 103 includes hafnium, zirconium, and oxygen such that, for example, ferroelectric film 103 may be substantially pure or pure HZO. Ferroelectric film 103 includes large crystalline grains 401 having grain sizes GS₁, GS₂, GS₃, respectively, for each of grains 302, 303, 304 (or for samples of grains). Grain sizes GS₁, GS₂, GS₃ may be determined using any suitable technique or techniques discussed with respect to FIG. 3. Notably, FIG. 4 illustrates that such grain sizes may be measured relative to the orientation of electrodes 101, 102 and ferroelectric film 103.

For example, in some embodiments, as shown with respect to grain 402, the grain size may be measured as distance GS₁ across centerline (CL) of grain 402 such that the centerline is orthogonal to thickness t_{FE}. In the example of FIG. 4 the centerline is vertical (e.g., in the z-dimension) whereas in FIG. 3, the centerline was horizontal (e.g., in the x-y plane). Generally, the centerline may be in any orientation such that it is aligned with a planarity of electrodes 101, 102 and ferroelectric film 103.

In some embodiments, as shown with respect to grain 403, the grain size may be measured as a maximum distance GS₂ across grain 403 such that the maximum distance GS₂ is determined as the greatest distance cross grain 303 in the x-z plane (e.g., along the cross-section). In this context, the orientation of electrodes 101, 102 and ferroelectric film 103 is not material to the grain size GS₂.

In some embodiments, as shown with respect to grain 404, the grain size may be measured as a maximum distance GS₄ across grain 304 attained along a line orthogonal to thickness t_{FE}. For example, vertical scan lines may be run across vertical positions (e.g., positions in the x-dimensions) of grain 404, and the maximum measured distance across grain 404 may be used as grain size GS₃. For example, the scan lines used to determine maximum distance GS₄ may horizontal, vertical, or in any other orientation such that the orientation is orthogonal to thickness t_{FE}.

As discussed with respect to FIG. 4, once the grain sizes of grains 402, 403, 404 are determined, grain size GS_{FE} of ferroelectric film 103 may be determined using any suitable technique or techniques such as a mean of the grain sizes, a median of the grain sizes, a maximum of the grain sizes, or the like. The grain size GS_{FE} determined for ferroelectric film 103 with respect to FIG. 4 may be any value and have any ratio with respect to thickness t_{FE} of ferroelectric film 103 discussed above.

FIG. 5 is a chart 500 illustrating exemplary ferroelectric layer characteristics inclusive of thickness and grain size as the ferroelectric layer is grown and subsequently etched back, arranged in accordance with some embodiments of the disclosure. As shown in FIG. 5, when an HZO layer or film is grown 501 (and optionally annealed) to various thicknesses, the HZO layer has a characteristic grain size 502 that depends on the growth thickness 503 such that the grain size 502 increases with increasing thickness 503. Although illustrated as a linear relationship 504, the grain size to thickness may have any monotonically increasing relationship.

For example, an advantageously larger grain size GS1, for polarity increased polarity, may be attained by depositing and annealing the HZO layer to a high thickness t1, as illustrated at point 511. However, as discussed, such greater thicknesses, such as thickness t1, are disadvantageous in terms of requiring a high operational voltage of the capacitor. But the larger grain sizes cannot be attained at reduced thicknesses such as thickness t2. Instead, a substantially smaller grain size GS1 is attained when the HZO layer is grown to thickness t2, as illustrated at point 512. To attain both reduced thickness t2 and larger grain size GS1, the HZO layer is first grown 501 to thickness t1, attaining grain size GS1, and then etched back 505 (e.g., using atomic layer etch) to thickness t2. Thereby the advantageously small thickness t2 and greater grain size GS1 are attained in the HZO capacitor film, as illustrated at point 513. Furthermore, the etch back 505 and prior growth 501 provide a high-quality low variability HZO capacitor film.

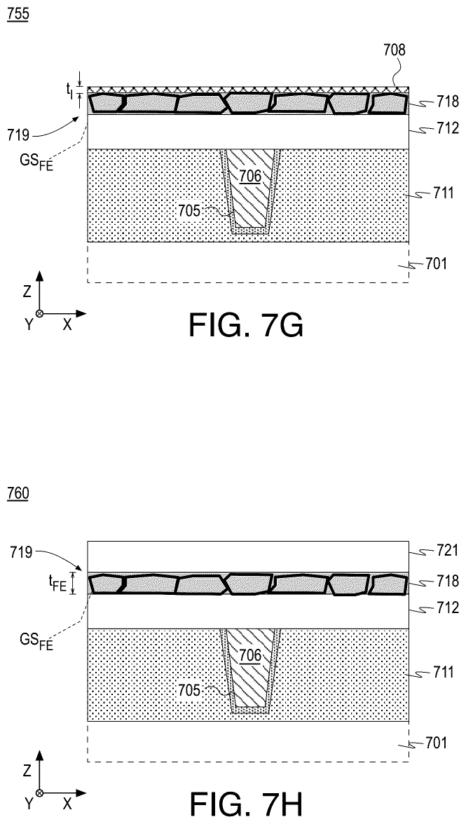

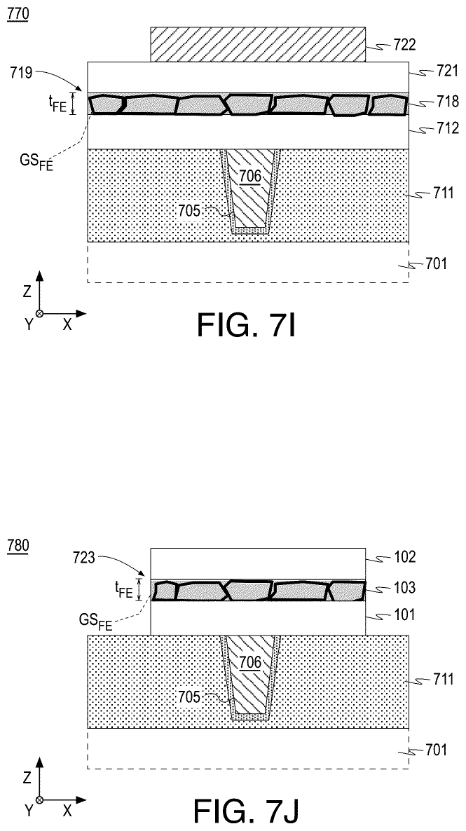

FIG. 6 is a flow diagram illustrating methods 600 for forming a capacitor having a thin ferroelectric layer including hafnium, zirconium, and oxygen with large crystalline grains or crystallites, arranged in accordance with some embodiments of the disclosure. Methods 600 may be practiced, for example, to fabricate any of ferroelectric capacitor or capacitor structures discussed herein. FIGS. 7A, 7B, 7C, 7D, 7E, 7F, 7G, 7H, 7I, 7J, and 7K are cross-sectional views of capacitor structures evolving as methods 600 are practiced, arranged in accordance with some embodiments of the disclosure. Although illustrated with respect to fabrication of a thin film capacitor, methods 600 may be used to form any capacitor structure. For example, methods 600 may be used to form deep trench capacitor 200, deep trench capacitor 800, dynamic random-access memory 900, multiple capacitor stacked memory device 1000, or any other capacitor structure discussed herein.

Methods 600 begin at input operation 601, where a workpiece including one or more material layers of a monolithic integrated circuit, for example, is received. In some embodiments, the workpiece is a large format (e.g., 300-450 mm) wafer and includes at least a device layer and a capacitor interconnect layer on a working surface of the wafer. Processing continues at operation 602, where a lower electrode layer is formed using any suitable technique or techniques such as blanket deposition techniques. The lower electrode layer may have any characteristics discussed with respect to electrode 101.

As shown in FIG. 7A, a capacitor structure 700 includes an interconnect 706 over a substrate 701, with interconnect 706 on a barrier layer 705. Interconnect 706 and barrier layer 705 may be embedded within insulator 711. In some embodiments, substrate 701 is a material used to manufacture integrated circuits inclusive of semiconductor materials such as, but not limited to, single crystal silicon, polycrystalline silicon, and silicon on insulator (SOI). In some embodiments, substrate 701 includes other semiconductor materials such as germanium, silicon germanium, or a suitable group III-V or group III-N compound. Substrate 701 may also include semiconductor materials, metals, dopants, and other materials commonly found in semiconductor substrates. In some embodiments, substrate 701 includes a device layer (e.g., transistor devices formed in a device layer), metallization stack(s), or other device layers. In some configurations, capacitors are fabricated above an access transistor in the back-end interconnect portion of the process flow, for example. Insulator 711 may be silicon dioxide, silicon nitride, silicon carbide, or a low-k dielectric such as carbon doped silicon oxide. Barrier layer 705 may include tantalum, tantalum nitride, or ruthenium, for example. Interconnect 706 includes a fill metal that may be cobalt, copper, tungsten, ruthenium, a combination thereof, or other metal(s).

Also as shown in FIG. 7A, capacitor structure 700 also includes a lower electrode material layer 712 (as formed at operation 602), which is to become electrode 101 of a thin film capacitor or other capacitor architecture. Electrode material layer 712 may include any material, materials, or material stack as discussed herein with respect to electrodes 101, 102. Electrode material layer 712 may be formed using any suitable technique or techniques such as blanket deposition. The blanket deposition may be performed with a physical vapor deposition (PVD) process, for example. In some embodiments, electrode material layer 712 is substantially pure or pure titanium nitride. For example, the titanium nitride layer may have a thickness in the range of 5 to 10 nm. However other materials or material systems may be used. For example, electrode material layer 712 may be or include tungsten, tantalum nitride, ruthenium, iridium, aluminum, copper, titanium, cobalt, chromium, molybdenum, nickel, gold, or platinum.

Returning to FIG. 6, methods 600 continue at operation 603, where a bulk HZO ferroelectric layer is blanket deposited in or over the lower electrode material layer. In some embodiments, the bulk HZO ferroelectric layer is deposited in direct contact with the lower electrode material layer. Any deposition technique or techniques known to be suitable for deposition of an HZO ferroelectric layer may be practiced at operation 603. In some embodiments, the HZO ferroelectric layer is deposited with an ALD process.

FIG. 7B illustrates a capacitor structure 710 similar to capacitor structure 700 after blanket deposition of a bulk HZO ferroelectric layer 713 on or over electrode material layer 712. Bulk HZO ferroelectric layer 713 may be deposited to any suitable thickness t_{B} to form large grain sizes (which may be added or set using a subsequent anneal) as discussed herein. In some embodiments, bulk HZO ferroelectric layer 713 has a thickness t_{B} of not less than 10 nm. In some embodiments, bulk HZO ferroelectric layer 713 has a thickness t_{B} of not less than 15 nm. In some embodiments, bulk HZO ferroelectric layer 713 has a thickness t_{B} of not less than 20 nm. In some embodiments, bulk HZO ferroelectric layer 713 has a thickness t_{B} in the range of 10 to 20 nm. In some embodiments, bulk HZO ferroelectric layer 713 has a thickness t_{B} in the range of 10 to 40 nm. In some embodiments, bulk HZO ferroelectric layer 713 has a thickness t_{B} of bout 15 nm. Other thicknesses may be used. In some embodiments, bulk HZO ferroelectric layer 713 is deposited at a thickness t_{B} that is about 3× a desired thickness of the HZO ferroelectric layer after etch back. As discussed with respect to FIG. 5, the grain size of bulk HZO ferroelectric layer 713 may be proportional to the thickness of bulk HZO ferroelectric layer 713. After deposition, bulk HZO ferroelectric layer 713 may include grains as illustrated herein below beginning in FIG. 7D.

Returning to FIG. 6, methods 600 continue at operation 604, where a metal layer may optionally be formed on the bulk HZO ferroelectric layer deposited at operation 603. Notably, the grain size of the bulk HZO ferroelectric layer may be established or better controlled when an anneal is performed in the presence of a metal layer on or over the bulk HZO ferroelectric layer. The optional metal layer may be formed using any suitable technique or techniques such as blanket deposition techniques.

FIG. 7C illustrates a capacitor structure 720 similar to capacitor structure 710 after formation of a metal layer 714 on bulk HZO ferroelectric layer 713. Electrode material layer 712 may include any material, materials, or material stack as discussed herein with respect to electrodes 101, 102. Metal layer 714 may be formed using any suitable technique or techniques such as blanket deposition. The blanket deposition may be performed with a physical vapor deposition (PVD) process, for example. In some embodiments, metal layer 714 is substantially pure or pure titanium nitride. For example, the titanium nitride layer may have a thickness in the range of 5 to 10 nm. However other materials or material systems may be used. For example, metal layer 714 may be or include tungsten, tantalum nitride, ruthenium, iridium, aluminum, copper, titanium, cobalt, chromium, molybdenum, nickel, gold, or platinum.

Returning to FIG. 6, methods 600 continue at operation 605, where an anneal is performed to set large grain sizes in the bulk HZO ferroelectric layer deposited at operation 603. As discussed, the presence of the metal layer formed at operation 603 may aid in the large grain size establishment and provide predictability in the resultant bulk HZO ferroelectric layer after anneal processing. The anneal may be performed using any suitable technique or techniques. In some embodiments, the is a relatively high temperature (e.g., 500° C. or above) and relatively short (e.g., 10 to 30 second) anneal. In some embodiments, spike anneal processing may be used.

FIG. 7D illustrates a capacitor structure 730 similar to capacitor structure 720 after anneal processing and illustrating large grains 715 formed in bulk HZO ferroelectric layer 713. Large grains 715 may have any characteristics discussed above with respect to grains 301, 401 and elsewhere herein. For example, the grain size of grains 715 of bulk HZO ferroelectric layer 713 may be not less than 15 nm, not less than 20 nm, or not less than 25 nm. In some embodiments, the grain size of grains 715 of bulk HZO ferroelectric layer 713 is in the range of 25 to 35 nm.

Returning to FIG. 6, methods 600 continue at operation 606, where the optional metal layer formed at operation 604 is removed using any suitable technique or techniques. In some embodiments, the optional metal layer is removed using selective etch techniques such as dry or wet etch techniques.

FIG. 7E illustrates a capacitor structure 740 similar to capacitor structure 730 after removal of metal layer 714 to expose a top surface 716 of bulk HZO ferroelectric layer 713. For example, metal layer 714 may be etched to expose a substantially planar top surface 716. Such that the substantially planar top surface 716 was formed at operation 603 using blanket deposition processing such as ALD.

Returning to FIG. 6, methods 600 continue at operation 607, where the exposed bulk HZO ferroelectric layer is etched back to form a thin HZO ferroelectric layer (e.g., a capacitor HZO ferroelectric layer or final HZO ferroelectric layer). The etch back may be performed using any suitable technique or techniques such as atomic layer etch (ALE), as illustrated. In particular, ALE allows for fine control of the final thickness of the thin HZO ferroelectric layer. In some embodiments, the etch back is performed using ALE with a fluorine based or fluorine containing chemistry. For example, the etch back may be performed using ALE with an HF (hydrogen fluoride) precursor or other fluorine based or containing precursor. In such embodiments, the resulting thin HZO ferroelectric layer includes fluorine.

FIG. 7F illustrates a capacitor structure 750 similar to capacitor structure 740 after etch back 717 of bulk HZO ferroelectric layer 713 to form a thin HZO ferroelectric layer 718 having large grains 719. As shown with respect to large grains 715, portions of the grains may be etched back during etch back 717 to form large grains 719 within thickness t_{FE} of HZO ferroelectric layer 718. HZO ferroelectric layer 718 may have any characteristics discussed with respect to ferroelectric film 103. For example, grains 719 of HZO ferroelectric layer 718 may be measured as discussed above and have any sizes such as grain size of not less than 15 nm, not less than 20 nm, not less than 25 nm, or grains size in the range of 25 to 35 nm. Furthermore, the ratio of the grain size GS_{FE} to the thickness t_{FE} may have any characteristics as discussed above such as being not less than five, not less than eight, or not less than ten. As discussed, in some embodiments, HZO ferroelectric layer 718 includes fluorine due to etch back 717 being performed using a fluorine based or fluorine containing chemistry such as ALE with an HF precursor or other fluorine based or containing precursor.

Returning to FIG. 6, methods 600 continue at operation 608, where the thinned HZO ferroelectric layer may be optionally treated and/or an optional dielectric layer may be deposited on the thinned HZO ferroelectric layer. For example, the thinned HZO ferroelectric layer may be treated to improve the qualities of the layer (e.g., uniformity, reduction of defects, stability, etc.). In some embodiments, the treatment includes an anneal operation. For example, a relatively high temperature (e.g., 500° C. or above) and relatively short (e.g., 10 to 30 second) anneal may be deployed to improve the HZO thinned HZO ferroelectric layer or film.

In addition, or in the alternative, a layer may be deposited on the thinned HZO ferroelectric layer to reduce leakage of the thinned HZO ferroelectric layer, for example. In some embodiments, the layer is a dielectric or insulative layer such as an oxide. For example, a low-leakage amorphous, polycrystalline, or single crystalline insulating thin film can be deployed. In some embodiments, the layer is very thin, such as having a thickness in the range of 0.5 to 2 nm. Example materials for dielectric or insulative layer include aluminum oxide (e.g., Al₂O₃), titanium oxide (e.g., TiO₂), hafnium oxide (e.g., HfO₂), silicon nitride (e.g., SiNₓ), or silicon oxide (e.g., SiO₂). The dielectric or insulative layer may be formed using any suitable technique or techniques such as CVD, PVD, or the like.

FIG. 7G illustrates a capacitor structure 755 similar to capacitor structure 750 after formation of a dielectric layer 756 on thin HZO ferroelectric layer 718. Dielectric layer 756 may have any characteristics discussed with respect to operation 608. For example, dielectric layer 756 may be substantially pure or pure aluminum oxide, titanium oxide, hafnium oxide, silicon nitride, or silicon oxide having thickness t₁ (e.g., in the z-dimension) in the range of 0.5 to 2 nm. Dielectric layer 756 may reduce leakage of thin HZO ferroelectric layer 718. In some embodiments, dielectric layer 756 fills grain boundaries and/or fills defective areas in thin HZO ferroelectric layer 718. Such grain boundaries and/or defective areas may arise due to non-uniform etching of bulk HZO ferroelectric layer 713 to form thin HZO ferroelectric layer 718.

Returning to FIG. 6, methods 600 continue at operation 609, where an upper electrode layer is formed using any suitable technique or techniques such as blanket deposition techniques. The upper electrode layer may have any characteristics discussed with respect to electrode 102. The upper electrode may be formed on the thinned HZO ferroelectric layer (as illustrated) or on a dielectric or insulative layer deposited at operation 608. Notably, dielectric layer 756 is not illustrated in FIGS. 7H-7K for the sake of clarity of presentation, but dielectric layer 756 may be present in some embodiments.

FIG. 7H illustrates a capacitor structure 760 similar to capacitor structure 750 after formation of an upper electrode material layer 721, which is to become electrode 102 of a thin film capacitor or other capacitor architecture. Electrode material layer 721 may include any material, materials, or material stack as discussed herein with respect to electrodes 101, 102. Electrode material layer 721 may be formed using any suitable technique or techniques such as blanket deposition using PVD, for example. In some embodiments, electrode material layer 721 is substantially pure or pure titanium nitride. For example, electrode material layer 721 may be substantially pure or pure titanium nitride having a thickness in the range of 5 to 10 nm. However other materials or material systems may be used. For example, electrode material layer 721 may be or include tungsten, tantalum nitride, ruthenium, iridium, aluminum, copper, titanium, cobalt, chromium, molybdenum, nickel, gold, or platinum.

Returning to FIG. 6, methods 600 continue at operation 610, where the capacitor material layers (e.g., lower electrode material layer, thin HZO layer, and lower electrode material layer) are patterned with any subtractive process(es) suitable for the various material layer compositions. Following capacitor patterning, any remaining interconnect levels of the integrated may be completed and the resultant structure maybe output at operation 611. For example, the upper electrode of the capacitor may be connected to other circuit nodes with an upper-level metallization. The resultant integrated circuit may be integrated in a memory device, processor device, or the like, packaged, assembled, and deployed in any suitable electronics device.

FIG. 7I illustrates a capacitor structure 770 similar to capacitor structure 760 after patterning a mask 722 on upper electrode material layer 721. Mask 722 defines a polygon area and position of a thin film capacitor, for example, relative to interconnect 706. Mask 722 may be formed with any lithographic process(es).

FIG. 7J illustrates a capacitor structure 780 similar to capacitor structure 770 after the patterning of the capacitor material layer stack including upper electrode material layer 721, thin HZO ferroelectric layer 718, and lower electrode material layer 712 to form a capacitor 723 including ferroelectric film 103 (e.g., a thin ferroelectric layer including hafnium, zirconium, and oxygen with large crystalline grains or crystallites) between electrodes 101, 102. In some embodiments, the capacitor material layer stack may be patterned with one or more plasma etch processes. Ferroelectric film 103, electrode 101, and electrode 102 may have any characteristics discussed herein. In some embodiments, HZO ferroelectric layer 718 includes fluorine due to the etch back performed at operation 607.

FIG. 7K illustrates a capacitor structure 790 similar to capacitor structure 780 after an upper-level interconnect 708 and barrier layer 707 have been fabricated in contact with electrode 102. Barrier layer 707 may provide for improved adhesion layer and may include, for example, tantalum, tantalum nitride, or ruthenium in contact with electrode 102. Interconnect 708 may include any suitable fill metal such as cobalt, tungsten, or copper. Capacitor 723, barrier layer 707 and interconnect 708 may be embedded in an insulator 724, which may be silicon dioxide, silicon nitride, silicon carbide, or the like.

As discussed, ferroelectric capacitor structures including may be deployed in any suitable capacitor and/or memory architecture such as deep trench capacitors, multiple capacitor arrays, planar capacitors, or others.

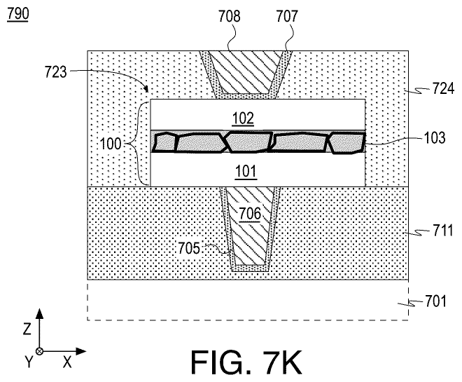

FIG. 8 illustrates a cross-sectional side view of an exemplary deep trench capacitor 800 having a thin ferroelectric layer including hafnium, zirconium, and oxygen with large crystalline grains or crystallites, arranged in accordance with some embodiments of the disclosure. Like components of deep trench capacitor 800 may have any characteristics discussed herein above. In the example of FIG. 8, deep trench capacitor 800 may be deployed over a bit line (i.e., capacitor over bit line, COB). As shown, deep trench capacitor 800 includes electrode 101, electrode 102, ferroelectric film 103, a metal via 804, interconnect 706, barrier layer 705, barrier layer 707, and interconnect 708. Electrode 101 is coupled to interconnect 706 and electrode 102 is coupled to interconnect 708 via metal via 804 and barrier layer 707. Deep trench capacitor 800 is formed within and embedded in insulator 724 (e.g., SiO2), for example.

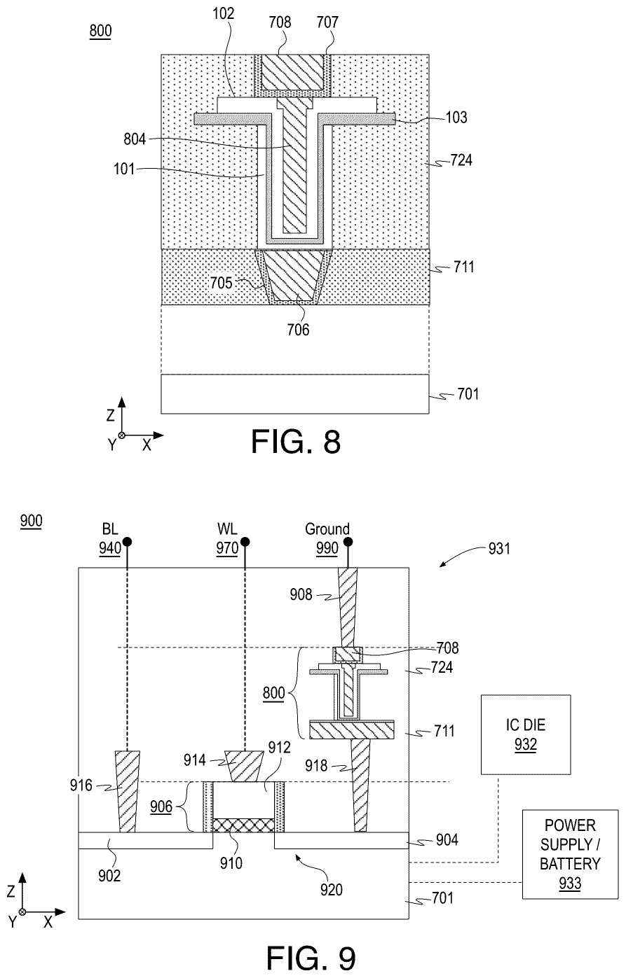

FIG. 9 illustrates a cross-section of an embedded dynamic random-access memory 900 including capacitor 800 having a thin ferroelectric layer including hafnium, zirconium, and oxygen with large crystalline grains or crystallites, arranged in accordance with some embodiments of the disclosure. Although illustrated with respect to deep trench capacitor 800 being deployed in embedded dynamic random-access memory 900, any capacitor or capacitor structure discussed herein may be used. As shown, embedded dynamic random-access memory 900 includes a select transistor 920 coupled to a capacitor such as deep trench capacitor 800. Transistor 920 includes a source region 902, a drain region 904, and a gate 906. Transistor 920 further includes a gate contact 914 on and electrically coupled to gate 906, a source contact 916 on and electrically coupled to source region 902, and a drain contact 918 on and electrically coupled to drain region 904. In some embodiments, capacitor 800 is above transistor 920 such that electrode 101 is coupled to drain contact 918 and electrode 102 is coupled to a via 908.

Also as shown, transistor 920 and capacitor 800 may be within an integrated circuit (IC) die 931. For example, IC die 931 may be monolithic IC device to perform particular tasks. In some embodiments, IC die 931 is a processor. In some embodiments, IC die 931 is a memory device. In some embodiments, IC die 931 is a system on a chip (SOC device). As shown, IC die 931 may be coupled to one or more additional IC dies such as IC die 932, which may be a processor, memory device, SOC, or any other component discussed herein. Also as shown, IC die 931 may be coupled to a power supply/battery 933 which may be or include any circuitry to power IC die 931. For example, dynamic random-access memory 900 may be deployed in a system including IC die 931, IC die 932, power supply/battery 933, and other components of an electronics product of any suitable form factor such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

In some embodiments, transistor 920 is a metal-oxide-semiconductor field-effect transistor (MOSFET or simply MOS transistors). Transistor 920 may be a planar transistor (as shown) or a nonplanar transistor such as a FinFET or a gate all around transistor such as a nanoribbon or nanowire transistor. Data is written into capacitor 800 as charge via a bit line (BL) 940 when access transistor 920 is turned on by applying a voltage on a word line WL 970. Interconnect 708 couples to a ground 990 through a metal via 908. In some embodiments, gate 906 is formed of at least two layers, gate dielectric layer 910 and gate electrode layer 912. Gate dielectric layer 910 may include one layer or a stack of layers including one or more of silicon dioxide and/or a high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Gate electrode layer 912 is on gate dielectric layer 910 and may comprise of at least one a P-type work-function metal (e.g., ruthenium, palladium, platinum, cobalt, nickel, and conductive metal oxides, e.g., ruthenium oxide) or a N-type work-function metal (e.g., hafnium, zirconium, titanium, tantalum, aluminum, alloys of these metals, and carbides of these metals such as hafnium carbide, zirconium carbide, titanium carbide, tantalum carbide, and aluminum carbide), depending on whether the transistor is to be a PMOS or an NMOS transistor. In some embodiments, the gate electrode layer 912 may comprise of a stack of two or more metal layers, where one or more metal layers are work-function metal layers and at least one metal layer is a conductive fill layer.

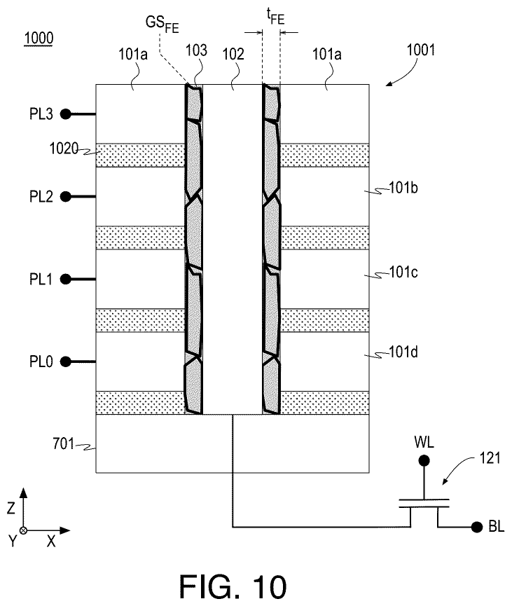

FIG. 10 illustrates a cross-sectional side view of a multiple capacitor stacked memory device 1000 including capacitors having a thin ferroelectric layer including hafnium, zirconium, and oxygen with large crystalline grains or crystallites, arranged in accordance with some embodiments of the disclosure. As shown in FIG. 10, memory device 1000 includes multiple ferroelectric capacitors 1001 having individual outer electrodes 101a-d, ferroelectric film 103, and a shared electrode 102. Memory device 1000 includes a vertically aligned array of ferroelectric capacitors 1001 such that each ferroelectric capacitor 1001 includes an electrode 101a-d, and a portion of electrode 102, which extends vertically through ferroelectric capacitors 1001, electrodes 101a-d, and ferroelectric film 103. Electrode 102 electrically connects to select transistor 121. Insulators 1020 surround electrode 102 and vertically separate and electrically isolate electrodes 101a-d.

Electrodes 101a-d may each be part of an integrated structure coupled to a corresponding plate line. For example, ferroelectric film 103 may be on an inner surface of a corresponding plate line, which is integral with corresponding electrodes 101a-d. In the example of FIG. 10, ferroelectric film 103 is on an inner surface of plate lines PL0, PL1, PL2, PL3, which are each integral with a corresponding electrodes 101a-d. Ferroelectric film 103 may have any characteristics discussed herein. For example, ferroelectric film 103 may have thickness t_{FE} (measured in the x-y plane) and a grain size G_{FE} (not shown in FIG. 10) as discussed below

Transistor 121 controls access to the memory array by electrically connecting (or not) electrode 102 to a bit line BL connected at a drain contact of transistor 121. When transistor 121 conducts, electrode 102 on electrically connected to bit line BL. The conduction of transistor 121 is controlled by the voltage signal applied to a gate electrode by a word line WL. Since electrode 102 is shared for all ferroelectric capacitors 1001 in the group, any bit stored in any of ferroelectric capacitors 1001 is accessible by single transistor 121. With transistor 121 accessing the entire memory array of ferroelectric capacitors 1001, individual control of ferroelectric capacitors 1001 is by electrodes 101a-d using plate lines PL0-PL3 in concert with transistor 121.

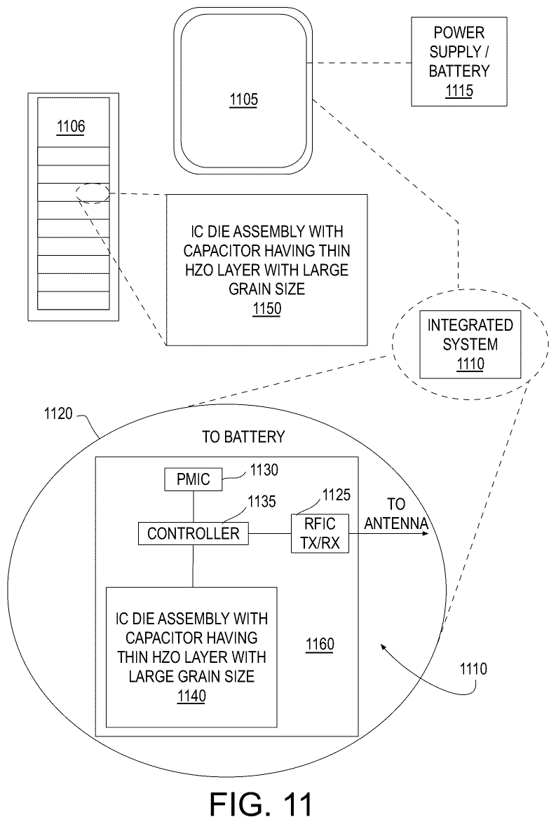

FIG. 11 illustrates exemplary systems employing an integrated circuit die including a memory having a thin ferroelectric layer including hafnium, zirconium, and oxygen with large crystalline grains or crystallites, in accordance with some embodiments. The system may be a mobile computing platform 1105 and/or a data server machine 1106, for example. Either may employ a memory cell, capacitor, or the like having a thin ferroelectric layer including hafnium, zirconium, and oxygen with large crystalline grains or crystallites as described elsewhere herein. Server machine 1106 may be any commercial server, for example including any number of high-performance computing platforms disposed within a rack and networked together for electronic data processing, which in the exemplary embodiment includes an IC die assembly 1150 with an IC die assembly including a capacitor having a thin ferroelectric layer including hafnium, zirconium, and oxygen with large crystalline grains or crystallites as described elsewhere herein. Mobile computing platform 1105 may be any portable device configured for each of electronic data display, electronic data processing, wireless electronic data transmission, or the like. For example, mobile computing platform 1105 may be any of a tablet, a smart phone, a laptop computer, etc., and may include a display screen (e.g., a capacitive, inductive, resistive, or optical touchscreen), a chip-level or package-level integrated system 1110, and a power supply/battery 1115. Although illustrated with respect to mobile computing platform 1105, in other examples, chip-level or package-level integrated system 1110 and a power supply/battery 1115 may be implemented in a desktop computing platform, an automotive computing platform, an internet of things platform, or the like. As discussed below, in some examples, the disclosed systems may include a sub-system 1160 such as a system on a chip (SOC) or an integrated system of multiple ICs, which is illustrated with respect to mobile computing platform 1105.

Whether disposed within integrated system 1110 illustrated in expanded view 1120 or as a stand-alone packaged device within data server machine 1106, sub-system 1160 may include memory circuitry and/or processor circuitry 1140 (e.g., RAM, a microprocessor, a multi-core microprocessor, graphics processor, etc.), a power management integrated circuit (PMIC) 1130, a controller 1135, and a radio frequency integrated circuit (RFIC) 1125 (e.g., including a wideband RF transmitter and/or receiver (TX/RX)). As shown, one or more IC dice, such as memory circuitry and/or processor circuitry 1140 may be assembled and implemented such that one or more include a capacitor having a thin ferroelectric layer including hafnium, zirconium, and oxygen with large crystalline grains or crystallites as described herein. In some embodiments, RFIC 1125 includes a digital baseband and an analog front end module further comprising a power amplifier on a transmit path and a low noise amplifier on a receive path). Functionally, PMIC 1130 may perform battery power regulation, DC-to-DC conversion, etc., and so has an input coupled to power supply/battery 1115, and an output providing a current supply to other functional modules. As further illustrated in FIG. 11, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1140 may provide memory functionality for sub-system 1160, high level control, data processing and the like for sub-system 1160. In alternative implementations, each of the SOC modules may be integrated onto separate ICs coupled to a package substrate, interposer, or board.

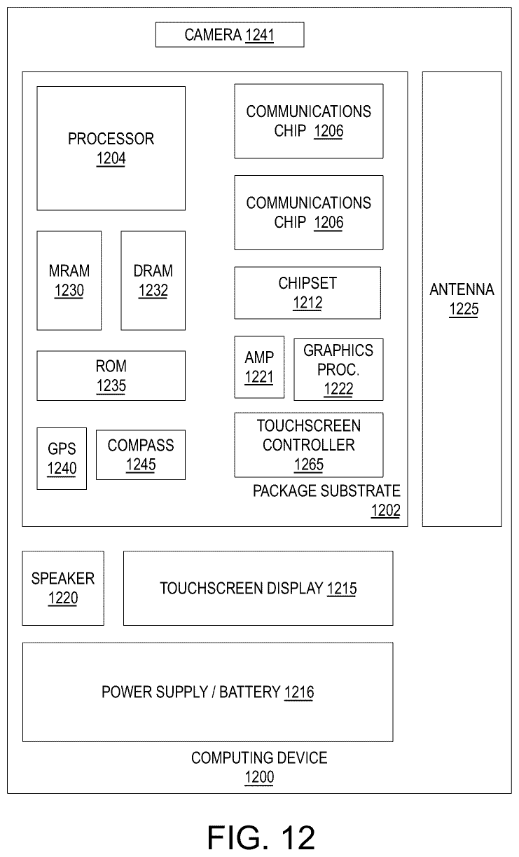

FIG. 12 is a functional block diagram of an electronic computing device 1200, in accordance with some embodiments. For example, device 1200 may, via any suitable component therein, employ a capacitor having a thin ferroelectric layer including hafnium, zirconium, and oxygen with large crystalline grains or crystallites in accordance with any embodiments described elsewhere herein. Device 1200 further includes a motherboard or package substrate 1202 hosting a number of components, such as, but not limited to, a processor 1204 (e.g., an applications processor). Processor 1204 may be physically and/or electrically coupled to package substrate 1202. In some examples, processor 1204 is within an IC assembly that includes a capacitor having a thin ferroelectric layer including hafnium, zirconium, and oxygen with large crystalline grains or crystallites as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1206 may also be physically and/or electrically coupled to the package substrate 1202. In further implementations, communication chips 1206 may be part of processor 1204. Depending on its applications, computing device 1200 may include other components that may or may not be physically and electrically coupled to package substrate 1202. These other components include, but are not limited to, volatile memory (e.g., DRAM 1232), non-volatile memory (e.g., ROM 1235), flash memory (e.g., NAND or NOR), magnetic memory (MRAM 1230), a graphics processor 1222, a digital signal processor, a crypto processor, a chipset 1212, an antenna 1225, touchscreen display 1215, touchscreen controller 1265, power supply/battery 1216, audio codec, video codec, power amplifier 1221, global positioning system (GPS) device 1240, compass 1245, accelerometer, gyroscope, speaker 1220, camera 1241, and mass storage device (such as hard disk drive, solid-state drive (SSD), compact disk (CD), digital versatile disk (DVD), and so forth, or the like.

Communication chips 1206 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1206 may implement any of a number of wireless standards or protocols, including, but not limited to, those described elsewhere herein. As discussed, computing device 1200 may include a plurality of communication chips 1206. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first electrode, a second electrode, and a ferroelectric film comprising hafnium, zirconium, and oxygen between the first electrode and the second electrode, the ferroelectric film comprising one or more grains and having a grain size of the ferroelectric film, and the ferroelectric film having a thickness extending between the first electrode and the second electrode, such that the grain size of the ferroelectric film is not less than five times the thickness of the ferroelectric film.

In one or more second embodiments, further to the first embodiments, the grain size of the ferroelectric film is not less than eight times the thickness of the ferroelectric film.

In one or more third embodiments, further to the first or second embodiments, the grain size of the ferroelectric film is not less than ten times the thickness of the ferroelectric film.

In one or more fourth embodiments, further to the first through third embodiments, the thickness of the ferroelectric film is not more than 5 nm and the grain size is not less than 20 nm.

In one or more fifth embodiments, further to the first through fourth embodiments, the ferroelectric film further comprises fluorine.

In one or more sixth embodiments, further to the first through fifth embodiments, the apparatus further comprises a dielectric layer between the ferroelectric film and the second electrode, such that the first electrode and the second electrode each comprise titanium and nitrogen.

In one or more seventh embodiments, further to the first through sixth embodiments, the grain size of the ferroelectric film comprises an average of a plurality of measured grain sizes each corresponding to an individual one of the one or more grains.

In one or more eighth embodiments, further to the first through seventh embodiments, the grain size of the ferroelectric film comprises an average of a plurality of measured grain sizes each corresponding to an individual one of the one or more grains.

In one or more ninth embodiments, further to the first through eighth embodiments, each of the plurality of measured grain sizes comprises a distance extending across a centerline of the grain substantially orthogonal to the thickness of the ferroelectric film.

In one or more tenth embodiments, further to the first through ninth embodiments, the apparatus further comprises a transistor coupled to a bit line and a word line and a capacitor coupled to the transistor, such that the capacitor comprises the first electrode, the second electrode, and the ferroelectric film, the capacitor comprising one of a planar capacitor or a trench capacitor.

In one or more eleventh embodiments, a system comprises a processor, a memory coupled to the processor, the memory comprising any apparatus or components discussed with respect to the first through tenth embodiments, and a power supply coupled to the processor and/or the memory.

In one or more twelfth embodiments, a system comprises a processor, a memory coupled to the processor, the memory comprising a ferroelectric material layer comprising hafnium, zirconium, and oxygen between a first electrode and a second electrode, the ferroelectric material layer having a thickness extending between and orthogonal to the first electrode and the second electrode and comprising a plurality of grains having an average grain width, the average grain width comprising an average of a grain width of each of the plurality of grains, each grain width extending orthogonal to the thickness, such the average grain width of the plurality of grains is not less than five times the thickness of the ferroelectric material layer, and a power supply coupled to the processor and/or the memory.

In one or more thirteenth embodiments, further to the twelfth embodiments, the average grain width of the plurality of grains is not less than ten times the thickness of the ferroelectric material layer.

In one or more fourteenth embodiments, further to the twelfth or thirteenth embodiments, the thickness of the ferroelectric material layer is not more than 5 nm and the average grain width of the plurality of grains is not less than 20 nm.

In one or more fifteenth embodiments, further to the twelfth through fourteenth embodiments, the ferroelectric material layer further comprises fluorine.

In one or more sixteenth embodiments, further to the twelfth through fifteenth embodiments, the memory further comprises a transistor coupled to a bit line and a word line, and a capacitor coupled to the transistor and to a ground, wherein the capacitor comprises the first electrode, the second electrode, and the ferroelectric material layer.

In one or more seventeenth embodiments, a method comprises depositing a bulk ferroelectric layer over a bottom electrode layer, the bulk ferroelectric layer comprising hafnium, zirconium, and oxygen, such that said depositing the bulk ferroelectric layer comprises depositing the bulk ferroelectric layer to a first thickness, atomic layer etching the bulk ferroelectric layer to form a ferroelectric capacitor layer, such that the ferroelectric capacitor layer has a second thickness not more than half the first thickness, and forming a top electrode over the ferroelectric capacitor layer.

In one or more eighteenth embodiments, further to the seventeenth embodiments, the method further comprises forming, prior to said atomic layer etching, a metal layer on the bulk ferroelectric layer, the metal layer comprising titanium and nitrogen, annealing the bulk ferroelectric layer and the metal layer, and removing, prior to said atomic layer etching, at least a portion of the metal layer.

In one or more nineteenth embodiments, further to the seventeenth or eighteenth embodiments, said depositing the bulk ferroelectric layer comprises atomic layer deposition, and, after said annealing, the bulk ferroelectric layer comprises one or more grains having a grain size of not less than 20 nm.

In one or more twentieth embodiments, further to the seventeenth through nineteenth embodiments, the method further comprises depositing, prior to said forming the top electrode, a dielectric layer on the ferroelectric capacitor layer, wherein the bulk ferroelectric layer is deposited on the bottom electrode layer, the bottom electrode layer comprising titanium and nitrogen.

In one or more twenty-first embodiments, further to the seventeenth through twentieth embodiments, the ferroelectric capacitor layer comprises one or more grains having a grain size, and wherein the grain size of the one or more grains is not less than five times the second thickness.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first electrode;
a second electrode; and
a ferroelectric film comprising hafnium, zirconium, and oxygen between the first electrode and the second electrode, the ferroelectric film comprising one or more grains and having a grain size of the ferroelectric film, and the ferroelectric film having a thickness extending between the first electrode and the second electrode, wherein the grain size of the ferroelectric film is not less than five times the thickness of the ferroelectric film.

2. The apparatus of claim 1, wherein the grain size of the ferroelectric film is not less than eight times the thickness of the ferroelectric film.

3. The apparatus of claim 1, wherein the grain size of the ferroelectric film is not less than ten times the thickness of the ferroelectric film.

4. The apparatus of claim 1, wherein the thickness of the ferroelectric film is not more than 5 nm and the grain size is not less than 20 nm.

5. The apparatus of claim 1, wherein the ferroelectric film further comprises fluorine.

6. The apparatus of claim 1, further comprising a dielectric layer between the ferroelectric film and the second electrode, wherein the first electrode and the second electrode each comprise titanium and nitrogen.

7. The apparatus of claim 1, wherein the grain size of the ferroelectric film comprises an average of a plurality of measured grain sizes each corresponding to an individual one of the one or more grains.

8. The apparatus of claim 1, wherein the grain size of the ferroelectric film comprises an average of a plurality of measured grain sizes each corresponding to an individual one of the one or more grains.

9. The apparatus of claim 8, wherein each of the plurality of measured grain sizes comprises a distance extending across a centerline of the grain substantially orthogonal to the thickness of the ferroelectric film.

10. The apparatus of claim 1, further comprising:
a transistor coupled to a bit line and a word line; and
a capacitor coupled to the transistor, wherein the capacitor comprises the first electrode, the second electrode, and the ferroelectric film, the capacitor comprising one of a planar capacitor or a trench capacitor.

11. A system, comprising:
a processor;
a memory coupled to the processor, the memory comprising:
a ferroelectric material layer comprising hafnium, zirconium, and oxygen between a first electrode and a second electrode, the ferroelectric material layer having a thickness extending between and orthogonal to the first electrode and the second electrode and comprising a plurality of grains having an average grain width, the average grain width comprising an average of a grain width of each of the plurality of grains, each grain width extending orthogonal to the thickness, wherein the average grain width of the plurality of grains is not less than five times the thickness of the ferroelectric material layer; and
a power supply coupled to the processor and/or the memory.

12. The system of claim 11, wherein the average grain width of the plurality of grains is not less than ten times the thickness of the ferroelectric material layer.

13. The system of claim 11, wherein the thickness of the ferroelectric material layer is not more than 5 nm and the average grain width of the plurality of grains is not less than 20 nm.

14. The system of claim 11, wherein the ferroelectric material layer further comprises fluorine.

15. The system of claim 11, wherein the memory further comprises a transistor coupled to a bit line and a word line, and a capacitor coupled to the transistor and to a ground, wherein the capacitor comprises the first electrode, the second electrode, and the ferroelectric material layer.

16. A method, comprising,
depositing a bulk ferroelectric layer over a bottom electrode layer, the bulk ferroelectric layer comprising hafnium, zirconium, and oxygen, wherein said depositing the bulk ferroelectric layer comprises depositing the bulk ferroelectric layer to a first thickness;
atomic layer etching the bulk ferroelectric layer to form a ferroelectric capacitor layer, wherein the ferroelectric capacitor layer has a second thickness not more than half the first thickness; and
forming a top electrode over the ferroelectric capacitor layer.

17. The method of claim 16, further comprising:
forming, prior to said atomic layer etching, a metal layer on the bulk ferroelectric layer, the metal layer comprising titanium and nitrogen;
annealing the bulk ferroelectric layer and the metal layer; and
removing, prior to said atomic layer etching, at least a portion of the metal layer.

18. The method of claim 17, wherein said depositing the bulk ferroelectric layer comprises atomic layer deposition, and, after said annealing, the bulk ferroelectric layer comprises one or more grains having a grain size of not less than 20 nm.

19. The method of claim 18, further comprising:
depositing, prior to said forming the top electrode, a dielectric layer on the ferroelectric capacitor layer, wherein the bulk ferroelectric layer is deposited on the bottom electrode layer, the bottom electrode layer comprising titanium and nitrogen.

20. The method of claim 16, wherein the ferroelectric capacitor layer comprises one or more grains having a grain size, and wherein the grain size of the one or more grains is not less than five times the second thickness.
